(19) United States
(12) Patent Application Publication
(10) Pub. No.: US 2017/0317489 A1
(43) Pub. Date: Nov. 2, 2017

(54) Method For Overcoming Influence Of Out-Flowing Current On Bus Differential Protection

(71) Applicants: STATE GRID CORPORATION OF CHINA, Beijing (CN); CHINA ELECTRIC POWER RESEARCH INSTITUTE, Beijing (CN); CENTER CHINA GRID COMPANY LIMITED, Wuhan (CN)

(72) Inventors: Dingxiang DU, Beijing (CN); Huanzhang LIU, Beijing (CN); Zexin ZHOU, Beijing (CN); Xingguo WANG, Beijing (CN)

(73) Assignees: STATE GRID CORPORATION OF CHINA, Beijing (CN); CHINA ELECTRIC POWER RESEARCH INSTITUTE, Beijing (CN); CENTER CHINA GRID COMPANY LIMITED, Wuhan (CN)

(21) Appl. No.: 15/520,850

(22) PCT Filed: Aug. 24, 2015
(86) PCT No.: PCT/CN2015/087922

§ 371 Date: Apr. 21, 2017

(30) Foreign Application Priority Data
Nov. 26, 2014 (CN) 201410704737.1

(51) Int. Cl. H02H 7/22; G06F 1/28; G01R 19/25

(52) U.S. Cl. CPC H02H 7/22; G01R 19/25; G06F 1/28

(57) ABSTRACT

The invention provides a method for overcoming the influence of out-flowing current on bus differential protection. The method comprises the following steps: acquiring and processing branch current signals; selecting a fault bus, and determining the branch current with maximum amplitude from branches connected with the fault bus; calculating differential current and restraint current of a large differential element, and determining whether the large differential element acts. The method for overcoming the influence of out-flowing current on bus differential protection does not need to reduce the braking coefficient during splitting operation in a two-bus connecting mode, can adaptively improve the sensitivity of bus differential protection under an internal fault in the presence of out-flowing current, and simultaneously ensures the reliability under an external fault.

### FIELD OF THE INVENTION

The present invention belongs to the technical field of relay protection of power systems, and specifically relates to a method for overcoming the influence of out-flowing current on bus differential protection.

### BACKGROUND

Bus protection generally adopts the differential protection principle. The differential protection has been most widely applied, for it is simple in principle, is not influenced by oscillation and has many other advantages. However, the problem of the out-flowing current during the internal fault in practical application has become a major factor influencing its security and reliability. The present invention puts forward a countermeasure for overcoming the influence of out-flowing current on bus differential protection.

A large differential element and a small differential element are generally configured for two-bus connecting bus protection. The large differential element is used for judging whether a fault occurs in its protection scope, while the small differential element is used for selecting and removing a fault bus. When two buses operate in a splitting way and are electrically connected with each other via a surrounding power network, one bus faults and the other sound bus has power supply. The fault current supplied from the power supply to a fault point necessarily flows out of the non-fault bus via a branch connected with the non-fault bus, and flows to the fault point via a branch connected with the fault bus, e.g., İ₃ in FIG. 1 of the specification is out-flowing current. As for a conventional percentage restraint differential algorithm, the current has no influence on large differential current, but increases the restraint current, leading to sensitivity decline of large differential percentage restraint criteria, and even leading to missing of the overall bus differential protection due to missing of the large differential protection in severe cases. Thus, some manufacturers handle such situation by internally reducing the large differential percentage restraint coefficient. Two-bus and two-sectional connecting bus protection also has similar problems.

### SUMMARY

In order to overcome the defects of the prior algorithm, the present invention provides a method for overcoming the influence of out-flowing current on bus differential protection, which does not need to reduce the restraint coefficient during splitting operation in a two-bus connecting mode, can adaptively improve the sensitivity of bus differential protection for an internal fault in the presence of out-flowing current, and simultaneously ensures the reliability under an external fault.

Summary of the invention for realizing the object of the present invention includes the following steps:

The invention provides a method for overcoming the influence of out-flowing current on bus differential protection.

step 1, acquiring and processing branch current signals;

step 2, selecting a fault bus, and determining the branch current with maximum amplitude from the branches connected with the fault bus:

step 3, calculating differential current and restraint current of a large differential element, and judging whether the large differential element operates.

step 1 comprising the following steps:

step 1-1, acquiring current sampling values of all branches connected with a bus, and performing low-pass filtration to obtain a k^{th} current sampling value iⱼ(k) of the j^{th} branch, wherein j=1, 2, . . . , n, and n is the total number of branches connected with the bus;

step 1-2, performing Fourier transformation on the iⱼ(k) to obtain a real part Xⱼ and an imaginary part Yⱼ of the current phasor iⱼ of the j^{th} branch,

$${X}_{j} = \frac{1}{N} [ 2 {\sum }_{k = 1}^{N - 1} {i}_{j} ( k ) sin ( k \frac{2 π}{N} ) ]$$

$${Y}_{j} = \frac{1}{N} [ 2 {\sum }_{k = 1}^{N - 1} {i}_{j} ( k ) cos ( k \frac{2 π}{N} ) ]$$

Where in N is the number of sampling points of fundamental wave within one cycle; and

obtaining amplitude I_{jM} and phase angle θⱼ of İⱼ via the real part Xⱼ and the imaginary part Yⱼ:

$${I}_{jM} = \sqrt{\frac{{X}_{j}^{2} + {Y}_{j}^{2}}{2}}$$

$${θ}_{j} = arctg \frac{{Y}_{j}}{{X}_{j}} .$$

step 2 comprising the following steps:

step 2-1, calculating differential current and restraint current of a small differential element,

the differential current and the restraint current of the small differential element being respectively expressed by [symbol] and [symbol] ,

$$= \vert {\sum }_{j = 1}^{m} {\dot{I}}_{j} \vert$$

$$= {\sum }_{j = 1}^{m} \vert {\dot{I}}_{j} \vert$$

wherein, m is the number of all branches connected with a single-sectional bus;

step 2-2, if the differential current and the restraint current of the small differential element corresponding to a certain bus satisfy [symbol] >kᵣₑₛ₁ [symbol] , determining the bus as a fault bus, wherein kᵣₑₛ₁ is a percentage restraint coefficient of the small differential element, and is generally 0.6; and

step 2-3, selecting the branch current İₘₐₓ with maximum amplitude from the branches connected with the determined fault bus.

step 3 comprising the following steps:

step 3-1, calculating the differential current of the large differential element,

$${I}_{cd} = \vert {\sum }_{j = 1}^{n} {\dot{I}}_{j} \vert$$

wherein I_{cd} is the differential current of the large differential element;

step 3-2, calculating the restraint current of the large differential element,

I_{zd}=|(İ_{cd}−İₘₐₓ)−İₘₐₓ|

wherein I_{zd} is the restraint current of the large differential element, İ_{cd} is the differential current phasor of the large differential element, and

$${\dot{I}}_{cd} = {\sum }_{j = 1}^{n} {\dot{I}}_{j} ;$$

step 3-3, judging whether the large differential element operates, wherein if the percentage restraint criterion I_{cd}>kᵣₑₛI_{za} is satisfied, ie

$$\vert {\sum }_{j = 1}^{n} {\dot{I}}_{j} \vert > {k}_{res} \vert ( {\dot{I}}_{cd} - {\dot{I}}_{max} ) - {\dot{I}}_{max} \vert$$

it indicates the large differential element operates, otherwise, it indicates the large differential element does not operate, and kᵣₑₛ is the percentage restraint coefficient of the large differential element and is 0.8.

Compared with the closest prior art, the present invention has the following beneficial effects:

1. In the calculation process of a restraint quantity, the influence of out-flowing current is eliminated. The phase of İ_{cd}−İₘₐₓ is close to that of İₘₐₓ, and the amplitude of the phasor difference is further smaller than the existing typical restraint quantity, so that the sensitivity of a large differential element when out-flowing current flows out under an internal fault in existing bus protection is greatly improved under the condition that the differential quantity is not changed;

2. Under a normal condition or an external fault, |İ_{cd}| is unbalanced current |İ_{bp}|, and the criterion put forward by the present invention is evolved into |İ_{bp}|>k|İ_{bp}−2İₘₐₓ|; compared with the conventional criterion

$$\vert {\dot{I}}_{bp} \vert > {\sum }_{j = 1}^{n} \vert {\dot{I}}_{j} \vert ,$$

the restraint quantity using the novel algorithm is reduced over the conventional algorithm; however, |İ_{bp}| is unbalanced current under the external fault, and the value of |İ_{bp}| is very small under the condition that CT is unsaturated, so that the bus differential protection still can ensure the reliability and no mal-operation;

3. It can be obtained by comparison with the typical bus current differential criterion

$$\vert {\sum }_{j = 1}^{n} {\dot{I}}_{j} \vert > {\sum }_{j = 1}^{n} \vert {\dot{I}}_{j} \vert$$

that under the internal fault, the existing typical criterion and the criterion put forward by the present invention have the same action quantity

$$\vert {\sum }_{j = 1}^{n} {\dot{I}}_{j} \vert ,$$

the restraint quantity |(İ_{cd}−İₘₐₓ)−İₘₐₓ| of the criterion put forward by the present invention is not influenced by the bus out-flowing current and is smaller than the restraint quantity

$${\sum }_{j = 1}^{n} \vert {\dot{I}}_{j} \vert$$

of the existing criterion, so the sensitivity of the criterion put forward by the present invention is higher than that of the existing criterion; and under the external fault, the criterion put forward by the present invention has substantially the same reliability as the existing criterion.

### BRIEF DESCRIPTION OF THE DRAWINGS

FIG. 1 is a schematic diagram of out-flowing current of two-bus connecting internal fault in the prior art;

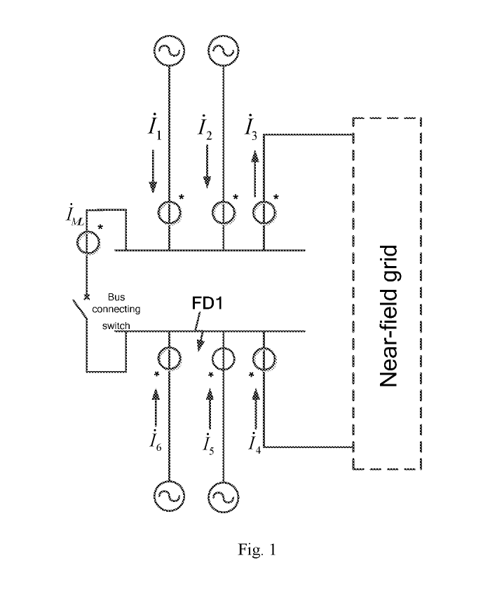

FIG. 2 is a flow diagram of a method for overcoming the influence of out-flowing current on bus differential protection in an embodiment of the present invention.

### DETAILED DESCRIPTION OF THE EMBODIMENTS

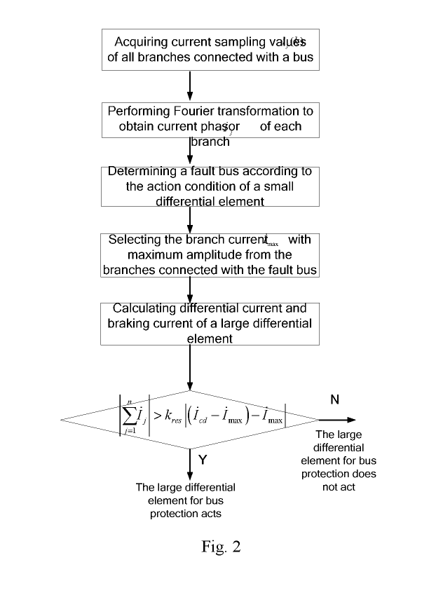

As shown in FIG. 2, the present invention provides a method for overcoming the influence of out-flowing current on bus differential protection, which does not need to reduce the braking coefficient during splitting operation in a two-bus connecting mode, can adaptively improve the sensitivity of bus differential protection for an internal fault in the presence of out-flowing current, and simultaneously ensures the reliability under an external fault.

Overcoming the influence of out-flowing current on bus differential protection, comprising the following steps:

step 1, acquiring and processing branch current signals;

step 2, selecting a fault bus, and determining the branch current with maximum amplitude from the branches connected with the fault bus:

step 3, calculating differential current and restraint current of a large differential element, and judging whether the large differential element acts.

step 1 comprising the following steps:

step 1-1, acquiring current sampling values of all branches connected with a bus, and performing low-pass filtration to obtain a k^{th} current sampling value iⱼ(k) of the j^{th} branch, wherein j=1, 2, . . . , n, and n is the total number of branches connected with the bus;

step 1-2, performing Fourier transformation on the iⱼ(k) to obtain a real part Xⱼ and an imaginary part Yⱼ of the current phasor iⱼ of the j^{th} branch,

$${X}_{j} = \frac{1}{N} [ 2 {\sum }_{k = 1}^{N - 1} {i}_{j} ( k ) sin ( k \frac{2 π}{N} ) ]$$

$${Y}_{j} = \frac{1}{N} [ 2 {\sum }_{k = 1}^{N - 1} {i}_{j} ( k ) cos ( k \frac{2 π}{N} ) ]$$

wherein N is the number of sampling points of fundamental wave within one cycle; and

obtaining amplitude I_{jM} and phase angle θⱼ of İⱼ via the real part Xⱼ and the imaginary part Yⱼ:

$${I}_{jM} = \sqrt{\frac{{X}_{j}^{2} + {Y}_{j}^{2}}{2}}$$

$${θ}_{j} = arc tg \frac{{Y}_{j}}{{X}_{j}} .$$

step 2 comprising the following steps:

step 2-1, calculating differential current and restraint current of a small differential element,

the differential current and the restraint current of the small differential element being respectively expressed by [symbol] and [symbol] ,

$$= \vert {\sum }_{j = 1}^{m} {\dot{I}}_{j} \vert$$

$$= {\sum }_{j = 1}^{m} \vert {\dot{I}}_{j} \vert$$

wherein, m is the number of all branches connected with a single-sectional bus;

step 2-2, if the differential current and the restraint current of the small differential element corresponding to a certain bus satisfy [symbol] >kᵣₑₛ₁ [symbol] , determining the bus as a fault bus, wherein kᵣₑₛ₁ is a percentage restraint coefficient of the small differential element, and is generally 0.6; and

step 2-3, selecting the branch current İₘₐₓ with maximum amplitude from the branches connected with the determined fault bus.

step 3 comprising the following steps:

step 3-1, calculating the differential current of the large differential element,

$${I}_{cd} = \vert {\sum }_{j = 1}^{n} {\dot{I}}_{j} \vert$$

wherein I_{cd} is the differential current of the large differential element;

step 3-2, calculating the restraint current of the large differential element,

I_{zd}=|(İ_{cd}−İₘₐₓ)−İₘₐₓ|

wherein I_{zd} is the restraint current of the large differential element, İ_{cd} is the differential current phasor of the large differential element, and

$${\dot{I}}_{cd} = {\sum }_{j = 1}^{n} {\dot{I}}_{j} ;$$

judging whether the large differential element acts, wherein if the ratio braking criterion I_{cd}>kᵣₑₛI_{zd} is satisfied,

$$\vert {\sum }_{j = 1}^{n} {\dot{I}}_{j} \vert > {k}_{res} \vert ( {\dot{I}}_{cd} - {\dot{I}}_{max} ) - {\dot{I}}_{max} \vert$$

it indicates the large differential element acts, otherwise, it indicates the large differential element does not act, and kᵣₑₛ is the percentage restraint coefficient of the large differential element and is 0.8.

Finally it should be noted that the described embodiments are merely a part, but not all, of the embodiments of the present invention. Based on the embodiments of the present invention, all of other embodiments obtained by those of ordinary skill without any creative effort are within the protection scope of the present application.

What is claimed is:

1. A method for overcoming the influence of out-flowing current on bus differential protection, comprising the following steps:
step 1, acquiring and processing branch current signals;
step 2, selecting a fault bus, and determining the branch current with maximum amplitude from the branches connected with the fault bus:
step 3, calculating differential current and restraint current of a large differential element, and judging whether the large differential element acts.

2. The method for overcoming the influence of out-flowing current on bus differential protection of claim 1 comprising the following steps:
step 1-1, acquiring current sampling values of all branches connected with a bus, and performing low-pass filtration to obtain a k^{th} current sampling value iⱼ(k) of the j^{th} branch, wherein j=1, 2, . . . , n, and n is the total number of branches connected with the bus;
step 1-2, performing Fourier transformation on the iⱼ(k) to obtain a real part Xⱼ and an imaginary part Yⱼ of the current phasor iⱼ of the j^{th} branch,
$${X}_{j} = \frac{1}{N} [ 2 {\sum }_{k = 1}^{N - 1} {i}_{j} ( k ) sin ( k \frac{2 π}{N} ) ]$$
$${Y}_{j} = \frac{1}{N} [ 2 {\sum }_{k = 1}^{N - 1} {i}_{j} ( k ) cos ( k \frac{2 π}{N} ) ]$$
wherein N is the number of sampling points of fundamental wave within one cycle; and
obtaining amplitude I_{jM} and phase angle θⱼ of İⱼ via the real part Xⱼ and the imaginary part Yⱼ:
$${I}_{jM} = \sqrt{\frac{{X}_{j}^{2} + {Y}_{j}^{2}}{2}}$$
$${θ}_{j} = arc tg \frac{{Y}_{j}}{{X}_{j}} .$$

3. The method for overcoming the influence of out-flowing current on bus differential protection of claim 2 comprising the following steps:
step 2-1, calculating differential current and restraint current of a small differential element, the differential current and the restraint current of the small differential element being respectively expressed by [symbol] and [symbol] ,
$$= \vert {\sum }_{j = 1}^{m} {\dot{I}}_{j} \vert$$
$$= {\sum }_{j = 1}^{m} \vert {\dot{I}}_{j} \vert$$
wherein, m is the number of all branches connected with a single-sectional bus;
step 2-2, if the differential current and the restraint current of the small differential element corresponding to a certain bus satisfy [symbol] >kᵣₑₛ₁ [symbol] , determining the bus as a fault bus, wherein kᵣₑₛ₁ is a percentage restraint coefficient of the small differential element, and is generally 0.6; and
step 2-3, selecting the branch current İₘₐₓ with maximum amplitude from the branches connected with the determined fault bus.

4. The method for overcoming the influence of out-flowing current on bus differential protection of claim 3 comprising the following steps:
step 3-1, calculating the differential current of the large differential element,
$${I}_{cd} = \vert {\sum }_{j = 1}^{n} {\dot{I}}_{j} \vert$$
wherein I_{cd} is the differential current of the large differential element;
step 3-2, calculating the restraint current of the large differential element,
I_{zd}=|(İ_{cd}−İₘₐₓ)−İₘₐₓ|

wherein I_{zd} is the restraint current of the large differential element, İ_{cd} is the differential current phasor of the large differential element, and
$${\dot{I}}_{cd} = {\sum }_{j = 1}^{n} {\dot{I}}_{j} ;$$
judging whether the large differential element acts, wherein if the ratio braking criterion I_{cd}>kᵣₑₛ₁I_{zd} is satisfied,
$$\vert {\sum }_{j = 1}^{n} {\dot{I}}_{j} \vert > {k}_{res} \vert ( {\dot{I}}_{cd} - {\dot{I}}_{max} ) - {\dot{I}}_{max} \vert$$
it indicates the large differential element acts, otherwise, it indicates the large differential element does not act, and kᵣₑₛ is the percentage restraint coefficient of the large differential element and is 0.8.
